(19) United States
(12) Patent Application Publication
(10) Pub. No.: US 2016/0366763 A1
(43) Pub. Date: Dec. 15, 2016

(54) INDICATOR SECURING APPARATUS

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: WEI MAO, Wuhan (CN); SHEN-FA TSAI, New Taipei (TW); JIE LI, Wuhan (CN)

(21) Appl. No.: 14/751,828

(22) Filed: Jun. 26, 2015

(30) Foreign Application Priority Data
Jun. 15, 2015 (CN) 201510325026.8

(51) Int. Cl. H05K 1/14

(52) U.S. Cl. CPC H05K 1/141; H05K 2201/048

(57) ABSTRACT

An indicator securing apparatus includes a bracket and a circuit board. The circuit board is configured to be mounted on a motherboard. The bracket includes a mounting portion, an extending portion extending from the mounting portion, and an engaging portion extending from the extending portion. The mounting portion receives and holds an indicator. The engaging portion is configured to resiliently engage with the circuit board, thereby enabling the indicator to be secured to the motherboard.

### FIELD

The subject matter herein generally relates to mountings.

### BACKGROUND

An indicator securing apparatus may be used to secure an indicator to a motherboard.

### BRIEF DESCRIPTION OF THE DRAWINGS

Implementations of the present technology will now be described, by way of example only, with reference to the attached figures.

FIG. 1 is an exploded, isometric view of an indicator securing apparatus.

FIG. 2 is similar to FIG. 1, but viewed from a different angle.

FIG. 3 is an assembled, isometric view of the indicator securing apparatus.

FIG. 4 is similar to FIG. 3, but viewed from a different angle.

FIG. 5 is a cross sectional view of the indicator securing apparatus of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure is described in relation to an indicator securing apparatus.

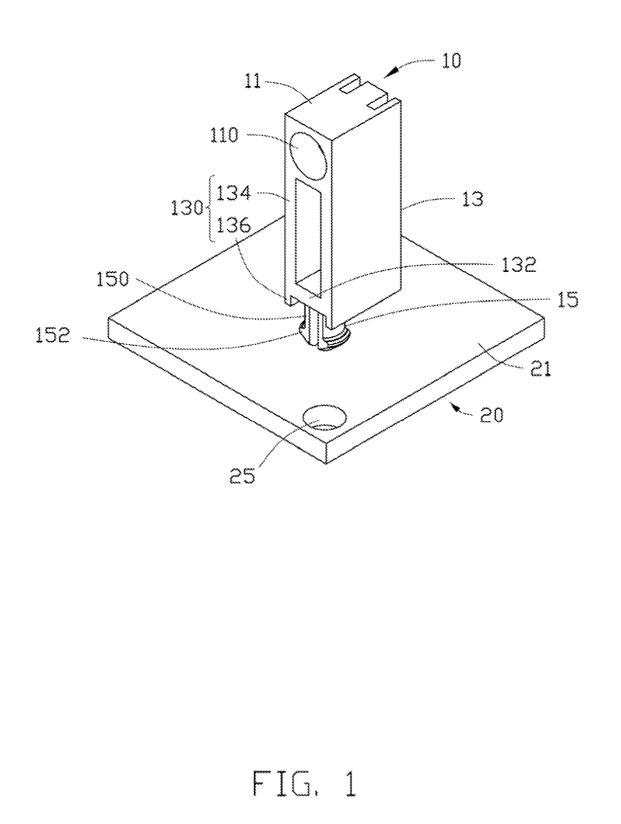

FIG. 1 illustrates an embodiment of an indicator securing apparatus. The indicator securing apparatus comprises a bracket 10 and a circuit board 20. The bracket 10 is configured to receive an indicator (not shown). The indicator gives a visual indication of a state.

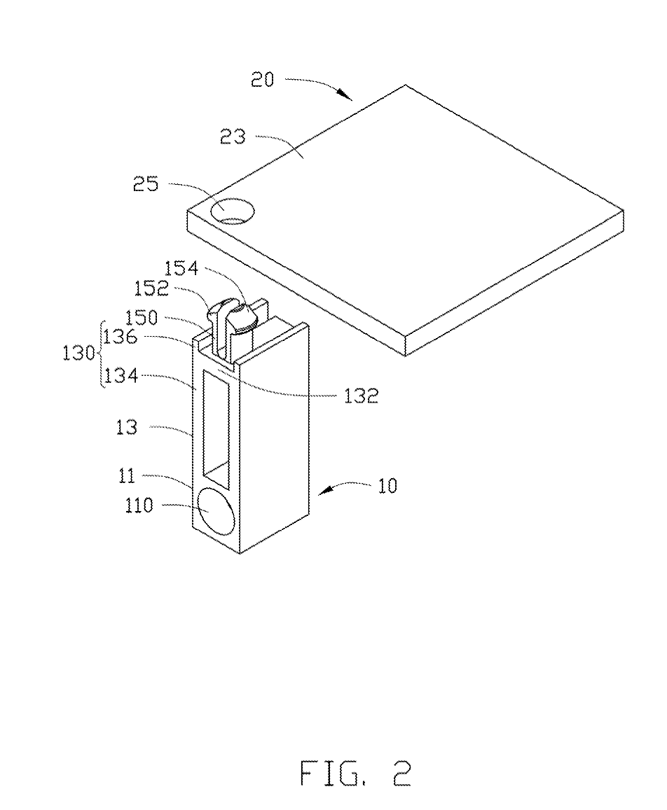

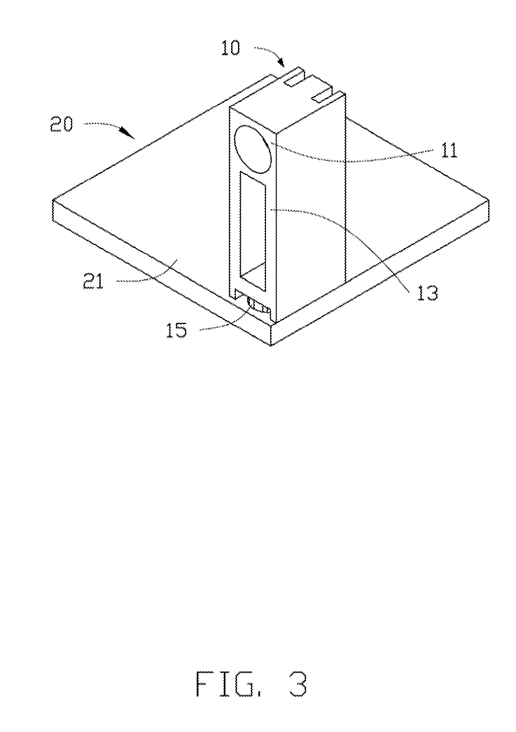

FIGS. 2 and 3 illustrate that the bracket 10 comprises a mounting portion 11, an extending portion 13 extending from the mounting portion 11, and an engaging portion 15 extending from the extending portion 13. The mounting portion 11 defines a mounting hole 110. The mounting hole 110 is configured to receive the indicator.

The extending portion 13 comprises two side portions 130 and a connecting portion 132. The two side portions 130 are substantially parallel to each other. The two side portions 130 extend from the mounting portion 11. The two side portions 130 are substantially perpendicular to the mounting portion 11. The connecting portion 132 is coupled between the two side portions 130. The connecting portion 132 is substantially perpendicular to the two side portions 130. Each side portion 130 comprises a top portion 134 and a bottom portion 136. The bottom portion 136 extends from the top portion 134. The connecting portion 132 is located between top portion 134 and bottom portion 136.

The engaging portion 15 comprises two resilient portions 150 and two hooks 152. The two resilient portions 150 extend from the connecting portion 132. The two resilient portions 150 are substantially perpendicular to the connecting portion 132. The two resilient portions 150 are substantially parallel to each other. Each hook 152 extends from a resilient portion 150. Each hook 152 comprises an inclined bottom surface 154.

The circuit board 20 comprises a first surface 21 and a second surface 23. The first surface 21 is substantially parallel to the second surface 23. The first surface 21 and the second surface 23 are located on opposite sides of the circuit board 20. The circuit board 20 defines an engaging hole 25.

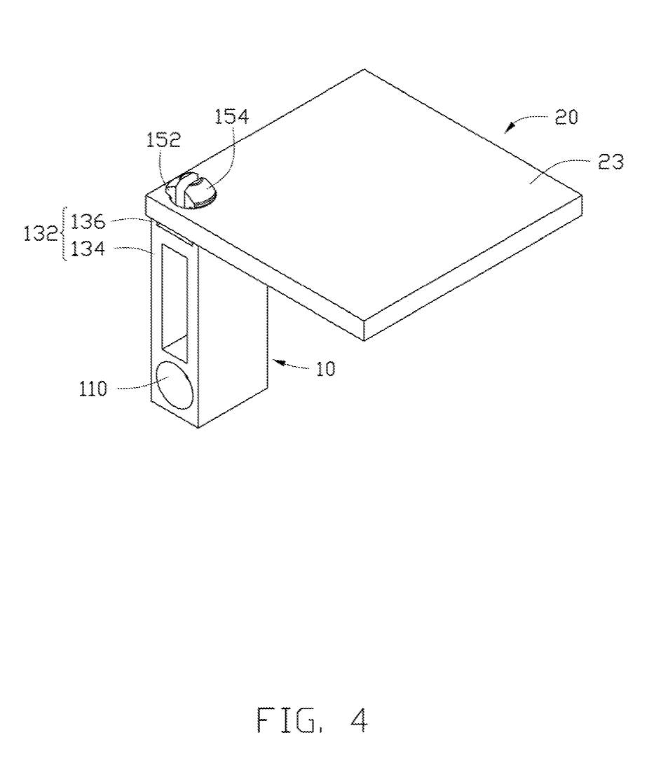

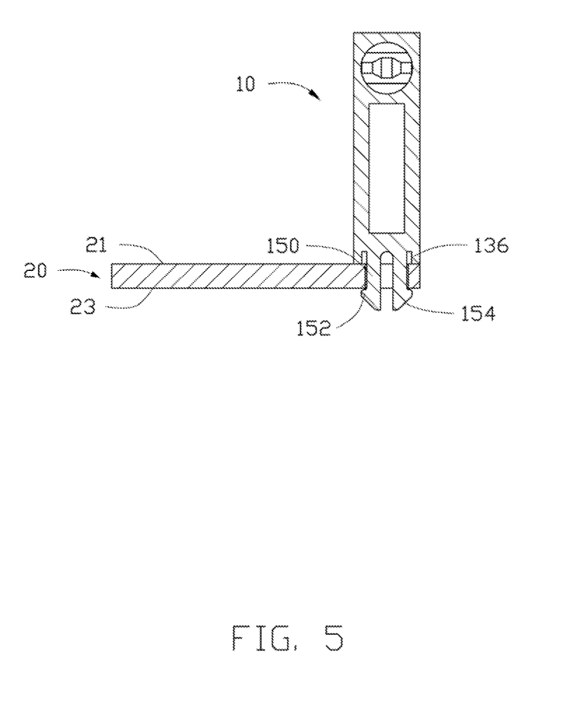

FIGS. 3-5 illustrate assembly of the indicator in the mounting hole 110. The bracket 10 is moved towards the circuit board 20, until the engaging portion 15 is aligned with the engaging hole 25. The bracket 10 is moved in a direction substantially perpendicular to the first surface 21. Each bottom surface 154 of the two hooks 152 is moved along a flange of the engaging hole 25. The two hooks 152 resist a sidewall of the engaging hole 25 after the two hooks 152 are moved into the engaging hole 25. The two resilient portions 150 are elastically deformed. Each bottom surface 154 of the two hooks 152 is moved along the flange of the engaging hole 25. The bracket 10 is moved, until the two hooks 152 extend through the engaging hole 25. The two resilient portions 150 restore, engaging the hook 152 with the second surface 23. The two resilient portions 150 are received in the engaging hole 25. The two bottom portions 136 resist the first surface 21. The bracket 10 is thus mounted on the circuit board 20. The circuit board 20 is mounted on a motherboard (not shown), thus the indicator is mounted on the motherboard.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure to the full extent indicated by the broad general meaning of the terms in which the appended claims are expressed.

What is claimed is:

1. An indicator securing apparatus comprising:
a circuit board mountable on a motherboard; and
a bracket having:
a mounting portion configured to receive an indicator;
an extending portion extending from the mounting portion; and
an engaging portion extending from the extending portion;
wherein the engaging portion is configured to engage with the circuit board thereby enabling the indicator to be secured to the motherboard.

2. The indicator securing apparatus of claim 1, wherein the circuit board comprises a first surface and a second surface, the engaging portion is configured to be engaged with the second surface, and the extending portion is located on the first surface.

3. The indicator securing apparatus of claim 2, wherein the first surface is substantially parallel to the second surface.

4. The indicator securing apparatus of claim 1, wherein the extending portion comprises two side portions and a connecting portion, the connecting portion is coupled between the two side portions, and the two side portions extend from the mounting portion.

5. The indicator securing apparatus of claim 4, wherein the connecting portion is substantially perpendicular to the two side portions.

6. The indicator securing apparatus of claim 4, wherein each side portion comprises a top portion and a bottom portion extending from the top portion, the connecting portion is located between one corresponding top portion and one corresponding bottom portion.

7. The indicator securing apparatus of claim 4, wherein the circuit board defines an engaging hole, the engaging portion comprises a resilient portion extending from the connecting portion and a hook extending from the resilient portion, the resilient portion is received in the engaging hole after the hook extends through the engaging hole, the hook is engaged with the circuit board.

8. The indicator securing apparatus of claim 7, wherein the resilient portion is substantially perpendicular to the connecting portion.

9. The indicator securing apparatus of claim 7, wherein the hook comprises an inclined bottom surface.

10. The indicator securing apparatus of claim 1, wherein the mounting portion defines a mounting hole configured to receive the indicator.

11. An indicator securing apparatus comprising:
a circuit board mountable on a motherboard; and
a bracket having:
a mounting portion configured to receive an indicator;
a resilient portion extending from the connecting portion configured to be received in circuit board; and
a hook extending from the resilient portion;
wherein the hook is configured to engage with the circuit board, thereby enabling the indicator to be secured to the motherboard.

12. The indicator securing apparatus of claim 11, wherein the bracket further comprises an extending portion, the extending portion extends from the mounting portion, and the resilient portion extends from the extending portion.

13. The indicator securing apparatus of claim 12, wherein the extending portion comprises two side portions and a connecting portion, the connecting portion is coupled between the two side portions, the resilient portion extends from the connecting portion, and the two side portions extend from the mounting portion.

14. The indicator securing apparatus of claim 13, wherein the connecting portion is substantially perpendicular to the two side portions.

15. The indicator securing apparatus of claim 13, wherein each side portion comprises a top portion and a bottom portion extending from the top portion, the connecting portion is located between one corresponding top portion and one corresponding bottom portion.

16. The indicator securing apparatus of claim 13, wherein the circuit board defines an engaging hole, the engaging portion comprises a resilient portion extending from the connecting portion and a hook extending from the resilient portion, the resilient portion is received in the engaging hole after the hook extends through the engaging hole, the hook is engaged with the circuit board.

17. The indicator securing apparatus of claim 16, wherein the resilient portion is substantially perpendicular to the connecting portion.

18. The indicator securing apparatus of claim 16, wherein the hook comprises an inclined bottom surface.

19. The indicator securing apparatus of claim 11, wherein the circuit board comprises a first surface and a second surface, the hook is configured to be engaged with the second surface, and the mounting portion is located on the first surface.

20. The indicator securing apparatus of claim 19, wherein the first surface and the second surface are located on opposite sides of the circuit board.
